(19) United States
(12) Patent Application Publication
(10) Pub. No.: US 2008/0280158 A1
(43) Pub. Date: Nov. 13, 2008

(54) Coated Sanitaryware Item

(75) Inventors: Armin Waidele, Alpirsbach (DE); Martin Surm, Schramberg (DE)

Correspondence Address: DUANE MORRIS LLP - Philadelphia;IP DEPARTMENT, 30 SOUTH 17TH STREET, PHILADELPHIA, PA, 19103-4196, US

(73) Assignee: Hansgrophe AG, Schiltach (DE)

(21) Appl. No.: 12/092,878

(22) PCT Filed: Nov. 7, 2006
(86) PCT No.: PCT/EP2006/010626

§ 371 Date: May 29, 2008

(30) Foreign Application Priority Data
Nov. 8, 2005 (DE) 102005054463.0

(51) Int. Cl. B32B 15/00; C23C 16/06; C23C 14/34

(52) U.S. Cl. 428/655; 428/615; 427/250; 204/298.13; 204/192.1

(57) ABSTRACT

An object, in particular an item of sanitaryware, has a base body, a first layer that is optionally present on the base body and a ruthenium-containing layer above this first layer. This ruthenium-containing layer has been applied using a PVD process and preferably consists of a ruthenium-containing alloy. This alloy is in particular a nickel-Chromium-ruthenium alloy. The invention also comprises a corresponding production process and a PVD target made from a nickel-chromium-ruthenium alloy.

The invention relates to coated objects, in particular coated items of sanitaryware, a method for producing them, and an associated target for a PVD (physical vapor deposition) method.

It has already been known for a long time to provide a wide variety of objects, in particular those which can be assigned in the broadest sense to the so-called household area, with coatings composed of inorganic or organic materials. Coatings of this type are applied on the one hand owing to functional requirements, e.g. for protection against corrosion, or on the other hand owing to decorative requirements, e.g. for producing a specific visual appearance. In this case, the same object is often coated for both functional and decorative reasons.

The coatings mentioned are of particular importance for all types of items of sanitaryware, particularly for sanitary fixtures, sanitary shower fittings and the like. This is because said items of sanitaryware on the one hand have to meet specific functional requirements, i.e. have to be for example highly corrosion-resistant, easy to clean, scratch-resistant, to name just a few of these requirements. On the other hand, they have to satisfy high decorative demands; i.e. it is necessary for example to provide lustrous or matte surfaces with a specific visual appearance. In this case, coatings and surfaces having a metallic appearance have gained more and more in importance in recent years. Thus, on the one hand, both bright and silvery white surfaces and rather semi lustrous surfaces are to be provided in the case of items of sanitaryware. On the other hand, the so-called aluminum visual appearance is indeed also sought, that is to say a surface which comes as close as possible to the visual appearance of aluminum.

Precisely in the case of items of sanitaryware it is often difficult to simultaneously meet the requirements made from a functional standpoint and a decorative standpoint. Thus, there are, on the one hand, coatings which, although sufficiently corrosion-resistant and the like, do not provide a satisfactory visual appearance. On the other hand, there are coatings which are more or less successful in attaining the desired visual appearance, but are not sufficiently corrosion-resistant or adversely affect existing corrosion resistance. Finally, there are coatings which can be applied to the corresponding objects only by very complicated methods and are accordingly not suitable for customary production methods, particularly on an industrial scale.

This is apparent for example in connection with the aluminum visual appearance mentioned above. Thus, there are conventional production methods for achieving such a visual appearance, such as, for example,

coating the objects with metal pigments,

using anodized aluminum,

applying aluminum to the object by vapor deposition, and subsequently applying a protective lacquer,

chromium-plating a surface composed of semi-bright nickel.

However, all these methods have the disadvantage already outlined that either they correspond too little to the desired aluminum color or they do not meet the stringent requirements of the sanitaryware market with regard to chemical and abrasion resistance.

Accordingly, the invention is based on the object of providing sanitaryware items and a method for producing them which can be used to realize the surfaces mentioned above. In particular, the aluminum visual appearance already mentioned is intended to be achieved in this case. At the same time, the objects thus provided are intended to meet the stringent functional requirements in the sanitaryware sector, that is to say in particular with regard to corrosion resistance, chemical resistance, abrasion resistance and the like.

This object is achieved by means of the object comprising the features of claim 1 and by means of the coating method comprising the features of claim 17. Preferred embodiments of said object and said method are presented in dependent claims 2 to 16 and 18 to 31, respectively.

The invention furthermore comprises a so-called target for a PVD (physical vapor deposition) method in accordance with claim 32 and the use of said target in accordance with claim 40. Particular embodiments of the claimed target are presented in dependent claims 33 to 39.

The wording of all the claims is hereby incorporated in the content of this description by reference.

The object according to the invention, in particular the item of sanitaryware, comprises a base body, to which the coating already explained is applied. Said base body can be coated directly according to the invention. It is often the case, however, that, if appropriate, at least one layer (referred to hereinafter as first layer) is applied to the base body, the (further) layer present according to the invention then being applied to said layer. In this case, said first layer preferably comprises at least one metal or at least one metal alloy.

The (further) layer on the base body or on the first layer is a ruthenium-containing layer according to the invention. As is known, ruthenium (Ru) belongs to the group of platinum metals and is distinguished by high corrosion resistance and chemical resistance, on the one hand, and by a metallically bright intrinsic color, on the other hand. In contrast to platinum or palladium, ruthenium is significantly more favorable to procure with regard to price.

In the case of the invention, it is preferred if the ruthenium-containing layer is applied by means of a PVD (physical vapor deposition) method. In this way, the ruthenium can be applied particularly uniformly to the surface to be coated. PVD methods are known to a person skilled in the art and will be explained in greater detail below in connection with the method according to the invention.

In particularly preferred embodiments of the object according to the invention, the ruthenium-containing layer comprises a ruthenium-containing alloy. The additional alloy constituents (alongside the ruthenium) make it possible to have a favorable influence on the surface color of the applied layer, on the one hand, and in particular the corrosion resistance and abrasion resistance of said layer, on the other hand. In this case, said ruthenium-containing alloy is a nickel-chromium-ruthenium (NiCrRu) alloy, in particular. Without wishing to restrict the invention here in any way, the nickel and ruthenium contained in the alloy influence the surface color, while the chromium contained in the alloy has an influence on the corrosion resistance, chemical resistance and abrasion resistance. Accordingly, the combination of the alloy constituents nickel, chromium and ruthenium is particularly advantageous.

In the already described embodiments of the object according to the invention, the ruthenium content of the ruthenium-containing layer, in particular of the alloy mentioned, is at least 12% by weight, preferably at least 15% by weight. In this case, ruthenium contents of between 15% by weight and 25% by weight, in particular between 20% by weight and 24% by weight, are particularly preferred.

The nickel contents of the layer or of the alloy are preferably at least 60% by weight, in particular at least 70% by weight. In this case, nickel contents of between 70% by weight and 85% by weight, in particular between 74% by weight and 78% by weight, are further preferred.

The preferred chromium contents in the layer or the alloy are at least 1% by weight. The chromium contents are preferably between 2% by weight and 4% by weight.

In accordance with the explanations above, in preferred embodiments of the invention, the ruthenium-containing layer correspondingly comprises a nickel-chromium-ruthenium alloy having nickel contents of between 74% by weight and 78% by weight, chromium contents of between 2% by weight and 4% by weight, and ruthenium contents of between 20% by weight and 24% by weight. Of these nickel-chromium-ruthenium alloys, an alloy having a nickel content of approximately 74% by weight, a chromium content of approximately 2% by weight and a ruthenium content of approximately 24% by weight is particularly preferred.

The thickness of the ruthenium-containing layer on the base body or on the first layer situated on the base body can be varied within wide limits. On the one hand, said layer must be thick enough to fulfill its function with regard to the chemical, corrosion and abrasion resistance. On the other hand, one will attempt to choose the layer thickness to be as small as possible in order to minimize the use of material, in particular the comparatively expensive material ruthenium. Layer thicknesses for the ruthenium-containing layer of between 0.1 μm and 5 μm are correspondingly preferred. Within this range, particular emphasis should be given to layer thicknesses of between 0.2 μm and 2 μm, preferably between 0.2 μm and 1 μm.

The base body for the object according to the invention can be produced from any desired material, in principle. In particular, this involves all types of materials which can be used in the field of sanitaryware. These are, on the one hand, preferably base bodies composed of metals or base bodies having metallic surfaces. In particular, base bodies composed of brass or zinc (in particular die-cast zinc) are involved here, such as are used for example in sanitary fixtures. On the other hand, emphasis should be given to base bodies composed of plastics or base bodies having plastic surfaces. In particular base bodies composed of ABS (acrylonitrile-butadiene-styrene copolymer), PA (polyamide) or ABS/PC (ABS copolymer with polycarbonate) are involved here. Such plastics are used for example as material for base bodies of sanitary shower fittings and the like.

In a development, in the case of the invention it is preferred if the base body or a first layer (in particular the topmost first layer) applied to the base body are mechanically surface-treated. Structures in the form of elevations and depressions can thus be introduced into the surface, which then bring about a particular surface effect after coating. This mechanical surface treatment can be, in particular, brushing or blasting, in particular sand-blasting.

As already explained, the first layers that are initially applied to the base body, if appropriate, preferably comprise metals or metal alloys. These can be applied in particular chemically (in an electroless fashion) or electrolytically (with current). In particular, copper, nickel and copper-nickel alloys should be mentioned here as metals and metal alloys. A chromium layer is preferably applied as the topmost first layer. In particular, this can be a matte chromium layer. The corresponding method steps are known to the person skilled in the art. The layer thicknesses of the first layer(s) are usually between 10 μm and 50 μm, and of course significantly smaller in the case of chromium.

In a development, at least one covering layer composed of a siloxane/polysiloxane can be situated above the ruthenium-containing layer. Coatings of this type are likewise known to the person skilled in the art and serve in the present case to prevent a so-called fingerprint effect or to improve ease of cleaning and repellency behavior with regard to water. Such coatings prevent greasy fingerprints from remaining on the object. The layer thicknesses of such covering layers are preferably <5 μm, in particular <1 μm.

As already illustrated, the invention also encompasses a method for producing the described objects, in particular items of sanitaryware. This method comprises the fact that, if appropriate, firstly at least one (first) layer is applied to a base body that is to be coated according to the invention. This (first) coating process preferably comprises applying at least one metal or at least one metal alloy. A ruthenium-containing layer is then applied to the base body directly or to the initially applied (first) layer(s). According to the invention, this is done with the aid of a PVD (physical vapor deposition) method. Physical vapor deposition methods of this type are known to the person skilled in the art. They involve a coating method in which the material that is to be deposited is initially present in solid form. The method generally takes place in a vacuum chamber under a vacuum. In this case, the vacuum chamber is loaded with the object to be coated and is then evacuated. The actual coating is then affected, whereupon the vacuum chamber is ventilated and the coated object is removed. Continuous methods can also be realized by means of corresponding lock systems. PVD methods are normally used for depositing thin layers within the range of a few nm through to a few μm.

In principle, the solid starting material for the coating can in this case be converted into the vapor phase by means of evaporation (using an arc or electron beam) or by means of cathode sputtering under a high vacuum and can then be deposited again on the object to be coated. Methods of this type are known to the person skilled in the art and need not be explained in any greater detail here. The experiments that were carried out in connection with the invention and will be explained below were carried out with the aid of cathode sputtering under a high vacuum. This method is also called hollow cathode gas flow sputtering.

In all essential points, in the case of the method according to the invention, reference can be made to the explanations regarding the already described object according to the invention. All corresponding features and the description thereof in connection with the object according to the invention are therefore expressly also incorporated in the content of the description of the method according to the invention.

Particular emphasis shall be given in this connection, however, to applying the ruthenium-containing alloy, in particular the nickel-chromium-ruthenium alloy already described in connection with the object according to the invention, in particular also with the preferred contents of ruthenium, nickel and chromium as mentioned there. Accordingly, in the method according to the invention, alloys having a nickel content of between 74% by weight and 78% by weight, a chromium content of between 2% by weight and 4% by weight and a ruthenium content of between 20% by weight and 24% by weight are preferably applied to the base body or the base body coated with the first layer. In particular, said alloy is the one having a nickel content of approximately 74% by weight, a chromium content of approximately 2% by weight and a ruthenium content of approximately 24% by weight. The layer thickness of the ruthenium-containing layer of preferably 0.1 μm to 5 μm, in particular 0.5 μm to 2 μm, shall also once again expressly be mentioned.

Directly in connection with the described object according to the invention and the described method according to the invention, the invention furthermore encompasses the so-called target for a PVD (physical vapor deposition) method, as presented in claim 32. Target is understood to mean, in the case of a PVD method, the solid material source from which the material for the coating originates. Said target is then evaporated or sputtered when carrying out the method in the sense of the above explanations, in order thus to be deposited again on the substrate, that is to say the object to be coated.

According to the invention, said target comprises a ruthenium-containing alloy, preferably a nickel-chromium-ruthenium alloy. Here, too, reference can be made to the corresponding explanations regarding the object according to the invention and the alloy defined there.

Accordingly, the NiCrRu alloy advantageously has a ruthenium content of at least 12% by weight, preferably at least 15% by weight. In such embodiments of the target, the ruthenium content of the alloy lies in particular between 15% by weight and 25% by weight, where within this range further emphasis should be given to ruthenium contents of between 20% by weight and 24% by weight.

The nickel contents of the alloy are at least 60% by weight, preferably at least 70% by weight. Within these preferred ranges, emphasis should be given to nickel contents of between 70% by weight and 85% by weight, where here once again nickel contents of between 74% by weight and 78% by weight are further preferred.

The chromium contents of the alloy are at least 1% by weight; said chromium contents are preferably between 2% by weight and 4% by weight.

In accordance with the previous explanations, the target according to the invention correspondingly preferably comprises nickel-chromium-ruthenium alloys having nickel contents of between 74% by weight and 78% by weight, chromium contents of between 2% by weight and 4% by weight, and ruthenium contents of between 20% by weight and 24% by weight. Particularly preferably, the target is produced from an alloy having a nickel content of approximately 74% by weight, a chromium content of approximately 2% by weight and a ruthenium content of approximately 24% by weight.

According to the invention, the described target is preferably used for coating items of sanitaryware such as sanitary fixtures, sanitary shower fittings and the like.

The previous portrayals clearly reveal that the invention is associated with a whole series of advantages.

Thus, the invention provides objects, in particular items of sanitaryware, which meet important functional requirements, on the one hand, and important decorative requirements, on the other hand. Thus, on the one hand, it is possible to produce objects having highly resistant surfaces as are desired precisely in the field of sanitary technology. In particular, the properties of corrosion resistance, chemical resistance and abrasion resistance should be mentioned in this case. On the other hand, the objects have according to the invention metallic surfaces (lustrous or rather matte or with an aluminum visual appearance, as desired) which accord with the customer's desires—here, too, in particular again in the field of sanitary technology—to a great extent. This simultaneous meeting of functional and decorative requirements particularly distinguishes the invention over the prior art. Moreover, ruthenium also represents a comparatively cost-effective element of the platinum group of the periodic table and, accordingly, can precisely be used for production in larger product series.

Moreover, the visual appearance of the surface can be varied whilst maintaining the surface resistance required for the respective purpose of use. This holds true particularly when using the preferred nickel-chromium-ruthenium alloys. The surface visual appearance, in particular the brightness and color thereof, can be varied here by the choice of the three alloy elements nickel, chromium and ruthenium, in particular within the preferred limits stated in the claims. Furthermore, a further possibility of variation also consists in the selection of the PVD method used and of its parameters in the coating method according to the invention. Thus, in PVD methods, reactive gases can additionally be introduced into the evaporated/sputtered coating material. Said reactive gases can be for example oxygen, nitrogen, acetylene or methane. Depending on the selection and mixture of the reactive gases, the brightness and color of the coating (ruthenium-containing layer) can also be influenced in this way. This constitutes a further preferred means for providing visual appearances desired by the customer precisely in the field of sanitary technology.

This selection can indeed also be made depending on the first layers situated on the base body. If a semilustrous visual impression (produced by a matte chromium layer, for example) is to be obtained, the ruthenium-containing layer is established by selection of a corresponding alloy composition and/or by selection of reaction gases such that it is not too bright or lustrous. Conversely, a bright or lustrous ruthenium-containing layer can be provided either in the case of rather matte or in the case of lustrous substrates.

The abovementioned and further advantages of the invention will become apparent from the following example in conjunction with the claims. Here the individual features can be realized in each case by themselves or in combination with one another.

### EXAMPLE

A hollow cathode gas flow sputtering installation was used for producing an object according to the invention. Installations of this type are known in principle to the person skilled in the art.

As already explained, in this case a so-called hollow cathode is used as the target of the PVD method. In the present case, said hollow cathode comprised a nickel-chromium-ruthenium alloy having 74% by weight of nickel, 2% by weight of chromium and 24% by weight of ruthenium. Said target is connected as a cathode in relation to an anode that was likewise situated in the installation, and a hollow cathode corona discharge is produced by applying a voltage. As a result, a sputtering of the cathode material takes place at the (inner) cathode surface. The material sputtered there is carried outward with the aid of an argon gas flow, to be precise in the direction of the substrate to be coated. In the present case, said substrate was the base body of a sanitary fixture composed of brass, which was coated in a known manner with a plurality of (first) layers, a matte chromium layer at the very top. Outside the hollow cathode, oxygen was fed in as a reactive gas.

In the case of the installation used in the example, a ruthenium-containing coating having a layer thickness of approximately 400 nm was produced during a coating duration of 3 minutes. An elemental analysis revealed that the composition of the coating corresponded to the composition of the target, that is to say that the coating had a nickel content of 74% by weight, a chromium content of 2% by weight and a ruthenium content of 24% by weight. The layer thickness was formed uniformly over the entire object.

The properties of the coatings obtained and thus of the coated object itself corresponded to the requirements to a great extent. This means, on the one hand, that the surface had a metallic appearance. The surface appearance was semilustrous, in accord with the topmost (first) matte chromium layer. On the other hand, tests revealed a very good chemical resistance, in particular to customary household cleaning agents, and excellent abrasion resistance. Furthermore, corrosion tests revealed very good corrosion resistance.

1. An object, preferably an item of sanitaryware such as a sanitary fixture, sanitary shower fitting and the like, characterized in that it is constructed from:
a base body,
if appropriate at least one first layer applied on the base body, the first layer preferably comprising at least one metal or at least one metal alloy, and
at least one ruthenium-containing layer on the base body or on the first layer.

2. The object as claimed in claim 1, characterized in that the ruthenium-containing layer is applied with the aid of a PVD (physical vapor deposition) method.

3. The object as claimed in claim 1, characterized in that the ruthenium-containing layer comprises a ruthenium-containing alloy, preferably a nickel-chromium-ruthenium alloy.

4. The object as claimed in claim 1, characterized in that the ruthenium content of the ruthenium-containing layer is at least 12% by weight, preferably at least 15% by weight.

5. The object as claimed in claim 4, characterized in that the ruthenium content is between 15% by weight and 25% by weight, preferably between 20% by weight and 24% by weight.

6. The object as claimed in claim 3, characterized in that the nickel content of the ruthenium-containing alloy is at least 60% by weight, preferably at least 70% by weight.

7. The object as claimed in claim 6, characterized in that the nickel content is between 70% by weight and 85% by weight, preferably between 74% by weight and 78% by weight.

8. The object as claimed in claim 3, characterized in that the chromium content of the ruthenium-containing alloy is at least 1% by weight, preferably between 2 and 4% by weight.

9. The object as claimed in claim 3, characterized in that the ruthenium-containing alloy has a nickel content of between 74% by weight and 78% by weight, a chromium content of between 2% by weight and 4% by weight and a ruthenium content of between 20% by weight and 24% by weight.

10. The object as claimed in claim 9, characterized in that the ruthenium-containing alloy is composed of approximately 74% by weight of nickel, approximately 2% by weight of chromium and approximately 24% by weight of ruthenium.

11. The object as claimed in claim 1, characterized in that the layer thickness of the ruthenium-containing layer is between 0.1 μm and 5 μm, preferably between 0.2 μm and 2 μm, in particular between 0.2 μm and 1 μm.

12. The object as claimed in claim 1, characterized in that the base body comprises metal or has metallic surfaces, the base body preferably being produced from brass or zinc.

13. The object as claimed in claim 1, characterized in that the base body comprises plastic or has plastic surfaces, the base body preferably being produced from ABS.

14. The object as claimed in claim 1, characterized in that the base body or at least one applied first layer is mechanically surface-treated, the surface treatment preferably being brushing or blasting, in particular sand-blasting.

15. The object as claimed in claim 1, characterized in that the first layer is a layer composed of copper, nickel or a copper-nickel alloy or is a chromium layer.

16. The object as claimed in claim 1, characterized in that at least one siloxane/polysiloxane covering layer is applied to the ruthenium-containing layer.

17. A process for coating objects, in particular items of sanitaryware such as sanitary fixtures, sanitary shower fittings and the like, wherein
if appropriate, at least one first layer, preferably composed of at least one metal or at least one metal alloy, is applied to a base body, and
at least one ruthenium-containing layer is applied to the base body or to the initially applied first layer with the aid of a PVD (physical vapor deposition) method.

18. The method as claimed in claim 17, characterized in that a ruthenium-containing alloy, preferably a nickel-chromium-ruthenium alloy, is applied as the ruthenium-containing layer.

19. The method as claimed in claim 17, characterized in that the ruthenium-containing layer has a ruthenium content of at least 12% by weight, preferably at least 15% by weight.

20. The method as claimed in claim 19, characterized in that the ruthenium content is between 15% by weight and 25% by weight, preferably between 20% by weight and 24% by weight.

21. The method as claimed in claim 18, characterized in that the nickel content of the ruthenium-containing alloy is at least 60% by weight, preferably at least 70% by weight.

22. The method as claimed in claim 21, characterized in that the nickel content is between 70% by weight and 85% by weight, preferably between 74% by weight and 78% by weight.

23. The method as claimed in claim 18, characterized in that the chromium content of the ruthenium-containing alloy is at least 1% by weight, preferably between 2% by weight and 4% by weight.

24. The method as claimed in claim 18, characterized in that the nickel content is between 74% by weight and 78% by weight, the chromium content is between 2% by weight and 4% by weight, and the ruthenium content is between 20% by weight and 24% by weight.

25. The method as claimed in claim 24, characterized in that the ruthenium-containing alloy is composed of approximately 74% by weight of nickel, approximately 2% by weight of chromium and approximately 24% by weight of ruthenium.

26. The method as claimed in claim 17, characterized in that the ruthenium-containing layer is applied with a layer thickness of between 1 μm and 5 μm, preferably between 0.2 μm and 2 μm, in particular between 0.2 μm and 1 μm.

27. The method as claimed in claim 17, characterized in that the base body comprises metal or has metallic surfaces, the base body preferably being produced from brass or zinc.

28. The method as claimed in claim 17, characterized in that the base body comprises plastic or has plastic surfaces, the base body preferably being produced from ABS.

29. The method as claimed in claim 17, characterized in that the base body or at least one first layer applied to the base body is mechanically surface-treated, preferably the base body or the first layer being brushed or blasted, in particular sand-blasted.

30. The method as claimed in claim 17, characterized in that a layer composed of copper, nickel and/or a copper-nickel alloy is applied or a layer composed of chromium is applied as the first layer.

31. The method as claimed in claim 17, characterized in that at least one siloxane/polysiloxane covering layer is applied to the ruthenium-containing layer.

32. A target for a PVD (physical vapor deposition) method, characterized in that it comprises a ruthenium-containing alloy, preferably a nickel-chromium-ruthenium alloy.

33. The target as claimed in claim 32, characterized in that the ruthenium content of the alloy is at least 12% by weight, preferably at least 15% by weight.

34. The target as claimed in claim 33, characterized in that the ruthenium content is between 15% by weight and 25% by weight, preferably between 20% by weight and 24% by weight.

35. The target as claimed in claim 32, characterized in that the nickel content of the alloy is at least 60% by weight, preferably at least 70% by weight.

36. The target as claimed in claim 35, characterized in that the nickel content is between 70% by weight and 85% by weight, preferably between 74% by weight and 78% by weight.

37. The target as claimed in claim 32, characterized in that the chromium content of the alloy is at least 1% by weight, preferably between 2% by weight and 4% by weight.

38. The target as claimed in claim 32, characterized in that the alloy comprises 74% by weight to 78% by weight of nickel, 2% by weight to 4% by weight of chromium and 20% by weight to 24% by weight of ruthenium.

39. The target as claimed in claim 38, characterized in that the alloy is composed of approximately 74% by weight of nickel, approximately 2% by weight of chromium and approximately 24% by weight of ruthenium.

40. The use of the PVD target as claimed in claim 32 for applying ruthenium-containing coatings to objects, in particular to items of sanitaryware such as sanitary fixtures, sanitary shower fittings and the like.
